(19) United States
(12) Patent Application Publication
(10) Pub. No.: US 2022/0316045 A1
(43) Pub. Date: Oct. 6, 2022

(54) SYSTEM AND METHOD FOR ION-ASSISTED DEPOSITION OF OPTICAL COATINGS

(71) Applicant: KLA Corporation, Milpitas, CA (US)

(72) Inventors: Guorong Vera Zhuang, Milpitas, CA (US); Gildardo Delgado, Livermore, CA (US); Evgeniia Butaeva, San Jose, CA (US); John Savee, San Francisco, CA (US); Gary V. Lopez Lopez, Milpitas, CA (US)

(21) Appl. No.: 17/696,636

(22) Filed: Mar. 16, 2022

Related U.S. Application Data
(60) Provisional application No. 63/168,284, filed on Mar. 31, 2021.

(51) Int. Cl. C23C 14/22; H01J 37/32; H01J 37/34; C23C 14/46; C23C 14/02; C23C 14/58

(52) U.S. Cl. CPC C23C 14/221; H01J 37/32724; H01J 37/3435; C23C 14/46; C23C 14/022; C23C 14/5806; G02B 1/12

(57) ABSTRACT

A method for ion-assisted deposition of optical coatings. The method may include performing one or more pre-deposition processes. The method may include performing evaporation using an evaporation assembly of an ion-assisted deposition system during ion-assisted deposition using a low energy ion beam source of the ion-assisted deposition system. The method may further include performing sputtering using a sputtering assembly of an ion-assisted deposition system. The evaporation assembly may include an evaporating target and an evaporator configured to directly evaporate target material from the evaporating target onto a surface of the one or more samples. The sputtering assembly may include a sputtering target and a sputtering high energy ion source configured to sputter target material from the sputtering target onto a surface of the one or more samples. The method may include performing one or more post-deposition treatment processes.

### CROSS-REFERENCE TO RELATED APPLICATIONS

The present applications claim the benefit under 35 U.S.C. § 119(e) of U.S. Provisional Application Ser. No. 63/168,284 filed Mar. 31, 2021, which is incorporated herein by reference in the entirety.

### TECHNICAL FIELD

The present disclosure relates generally to a system and method for ion-assisted deposition and, more particularly, to a system and method for ion-assisted deposition of optical coatings for vacuum ultraviolet (VUV) and extreme ultraviolet (EUV) applications.

### BACKGROUND

As the demand for integrated circuits having ever-smaller device features continues to increase, the need for improved sample fabrication approaches continues to grow. One such fabrication technology includes application of optical coatings to one or more surfaces of a sample. Conventional application methods produce low density, porous films that are susceptible to water and contamination uptake which makes them susceptible to damage under VUV irradiation. In addition, the coatings have a higher concentration of intrinsic defects that contain vacancies (e.g., color centers), defects (e.g., dangling bonds, dislocations, or the like), and impurities that can absorb VUV light and participate in further photo-induced degradation of the coating. Therefore, it would be desirable to provide a system and method that cures the shortfalls of the prior approaches.

### SUMMARY

An apparatus for ion-assisted deposition of optical coatings is disclosed. In embodiments, the apparatus comprises a low energy ion beam source configured to generate one or more low energy ion beams and direct the one or more low energy beams to a surface of one or more samples mounted on a sample stage, the low energy ion beam source configured to couple to one or more working gas supplies. In embodiments, the apparatus comprises a radiative heater positioned proximate to the one or more samples disposed on the sample stage, the radiative heater configured to heat the one or more samples. In embodiments, the apparatus comprises a gas inlet coupled to a fluorine gas supply source. In embodiments, the apparatus comprises an evaporator assembly, the evaporator assembly comprising an evaporator; and an evaporating target, the evaporator configured to directly evaporate target material from the evaporating target to a surface of the one or more samples, the apparatus configured to use the one or more low energy ion beams from the low energy ion beam source during evaporation from the evaporator assembly for generation of one or more optical coatings on a surface of the one or more samples.

### BRIEF DESCRIPTION OF DRAWINGS

The numerous advantages of the disclosure may be better understood by those skilled in the art by reference to the accompanying figures.

FIG. 1 is simplified block diagram of a sample fabrication system, in accordance with one or more embodiments of the present disclosure.

FIG. 2A is a simplified schematic view of a deposition sub-system of the one or more samples fabrication, in accordance with one or more embodiments of the present disclosure.

FIG. 2B is a simplified schematic view of a deposition sub-system of the one or more samples fabrication, in accordance with one or more embodiments of the present disclosure.

FIG. 2C is a simplified schematic view of a deposition sub-system of the one or more samples fabrication, in accordance with one or more embodiments of the present disclosure.

FIG. 3 illustrates a flow diagram depicting a method of depositing one or more layers of one or more optical coatings onto a surface of a sample, in accordance with one or more embodiments of the present disclosure.

FIG. 4 illustrates a flow diagram depicting a method of depositing one or more layers of one or more optical coatings onto a surface of a sample, in accordance with one or more embodiments of the present disclosure.

FIG. 5 illustrates a flow diagram depicting a method of depositing one or more layers of one or more optical coatings onto a surface of a sample, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

It is often desirable for coatings used in VUV and EUV applications to meet a number of requirements (e.g., high density, pinhole free, low defect concentration, and substantially nominal stoichiometry). Conventional application technologies, such as resistive or electron beam deposition technologies or magnetron or ion sputtering technologies, produce coatings which fail to meet one or more of the above requirements. For example, these conventional application techniques produce low density, porous films that are susceptible to water and contamination uptake which makes them susceptible to damage under VUV irradiation. In addition, the coatings also have a higher concentration of intrinsic defects (e.g., fluorine vacancies, oxygen interstitials and substantial, and the like), defects (e.g., dangling bonds, dislocations, or the like), and impurities that can absorb VUV light and participate in further photo-induced degradation of the coating. For instance, metal fluoride coatings (e.g., MgF₂, AlF₃, LaF₃, and the like) as deposited by old deposition methods may contain metal cluster defects. The small metal clusters embedded in the metal fluoride matrix are attributed to high energy plasma impact. The coating containing such localized metal cluster has been found to have high extinction coefficient k at DUV, which induces high extinction coefficient k in VUV as well. High extinction coefficient k is directly responsible for high absorption in spectral region specified above. Further, metal fluoride films produced using conventional evaporation technology have sub-stoichiometric fluorine concentrations. Further, metal fluoride coatings from sputtering deposition techniques were found to have higher density and increased refractive index in comparison to those produced by evaporation techniques. Nevertheless, although the refractive index is increased in the VUV spectral region it is accompanied by high VUV absorption. This source of absorption is attributed to preferential sputtering of light elements by high energy ions and is particularly undesirable for VUV applications. For example, high energy ion sputtering not only introduced sub-stoichiometric fluorine concentrations (Mg:F<2) from F-vacancies in magnesium fluorine (MgF2), but also excess metal forming magnesium (Mg) nano particle in the matrix. Both scenarios lead to high extinction coefficient, thus high absorption in VUV spectral region.

Embodiments of the present disclosure are directed to a system and method for ion-assisted deposition (IAD) of optical coatings. For example, the system and method for IAD may be configured to produce high density, stoichiometric coatings with low absorption in VUV and EUV. For instance, the system and method may use a low energy ion beam during evaporation (e.g., thermal evaporation, electron beam evaporation, and the like) for generation of optical coatings with high EUV/VUV optical performance. In this regard, the metal fluoride films deposited using the system and method may have an increase in fluoride ion concentration which enhances the coating density. Further, simultaneous evaporation (e.g., thermal evaporation, electron beam evaporation, and the like) with low energy ion beam bombardment may enhance surface diffusion of adatoms, while minimizing interstitial atoms and vacancies. Further, the stoichiometric composition of the deposited material may approach nominal values using the system and method.

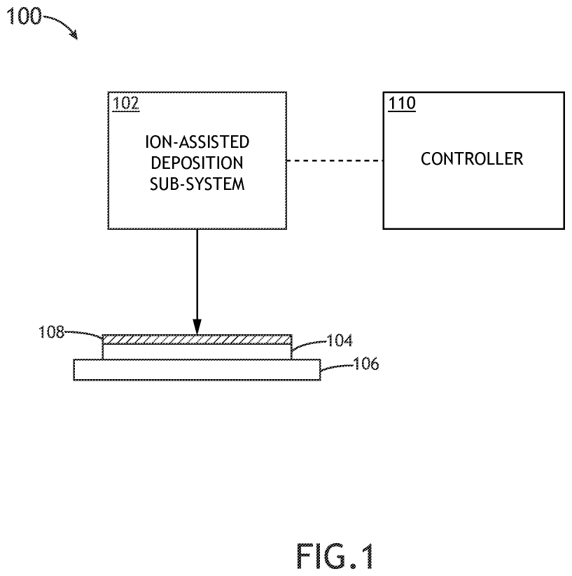

FIG. 1 illustrates a simplified block diagram of a sample fabrication system 100 for deposition of one or more optical coatings onto a surface of a sample, in accordance with one or more embodiments of the present disclosure.

In embodiments, the system 100 may include a deposition sub-system 102 (or deposition tool 102) configured to deposit one or more optical coatings 108 onto one or more surfaces of a sample 104 disposed on a sample stage 106. For example, the deposition sub-system 102 may be configured to deposit one or more layers of one or more optical coatings 108 onto one or more surfaces of the one or more samples 104. For purposes of the present disclosure, it is noted that the deposition sub-system 102 may be referred to as a deposition tool 102.

The one or more samples 104 may include any sample known in the art including, but not limited to, a wafer, a reticle, a photomask, and the like. The one or more samples 104 may be disposed on a sample stage 106 to facilitate movement of the one or more samples 104. For example, the sample stage 106 may be an actuatable stage. In one instance, the sample stage 106 may include, but is not limited to, one or more rotational stages suitable for selectively rotating the one or more samples 104 along a rotational direction. In another instance, the sample stage 106 may include, but is not limited to, one or more translational stages suitable for selectively translating the one or more samples 104 along one or more linear directions (e.g., x-direction, y-direction, and/or z-direction). In another instance, the sample stage 106 may include, but is not limited to, a rotational stage and a translational stage suitable for selectively translating the one or more samples 104 along a linear direction and/or rotating the one or more samples 104 along a rotational direction.

The deposition sub-system 102 may be configured to deposit any type of optical coating 108 onto a surface of the one or more samples 104. For example, the one or more optical coatings 108 may include one or more metal fluoride optical coatings such as, but not limited to, MgF₂, LaF₃, AlF₃, GdF₃, LuF₃, Na₃AlF₆, BaF₂, LiF, or the like, or a combination thereof. By way of another example, the one or more optical coatings 108 may include one or more anti-reflective (AR) optical coatings.

Although one or more embodiments of the present disclosure are directed to depositing one or more optical coatings, it is noted that the system 100 may be further configured to deposit onto beam splitters, mirrors, or used to form capping layers used to protect the optical element. For example, the deposition sub-system 102 may be configured to deposit one or more capping layers configured to protect detectors. For instance, the one or more capping layers may include, but are not limited to, B, Ru, Mo, carbon, TiO₂, Nb₂O₃.

Further, the deposition sub-system 102 may be configured to deposit any number of layers of the one or more optical coatings 108 onto a surface of the one or more samples 104. For example, the deposition sub-system 102 may be configured to deposit bi-layers (e.g., two layers). By way of another example, the deposition sub-system 102 may be configured to deposit multilayers (e.g., a plurality of layers).

The deposition sub-system 102 may be further configured to perform one or more in-situ substrate cleaning processes. In embodiments, the deposition sub-system 102 includes a thermal/e-beam evaporator to directly evaporate target material to substrates. The substrates are mounted on a rotatable holder with radiative heater in vicinity. A filament-less ion source connected with a working gas supply directs an ion beam to the substrates during evaporation. The ion beam impingement angle (a) can be adjusted by varying ion source angle with respect to the substrate surface normal to reduce preferential sputtering. A separate gas inlet allows F-containing gas to be introduced during postdeposition treatment, such as sample being annealed by radiative heater in F-containing environment. An ion source (e.g., ion gun) is also used for substrate in-situ cleaning before coating deposition.

The deposition sub-system 102 may be further configured to perform one or more post-deposition treatment processes. For example, the deposition sub-system 102 may be configured to perform post-deposition treatment annealing.

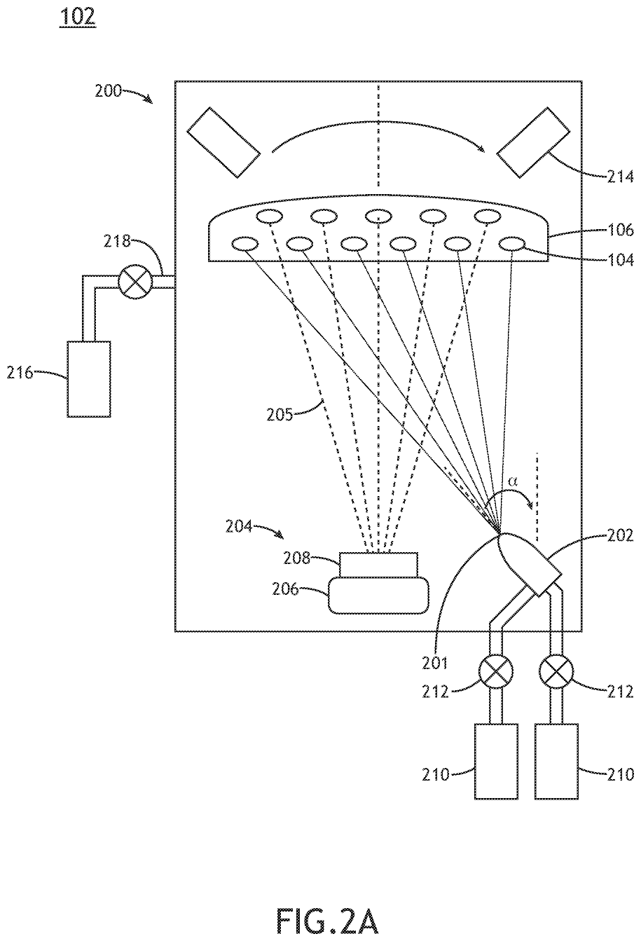

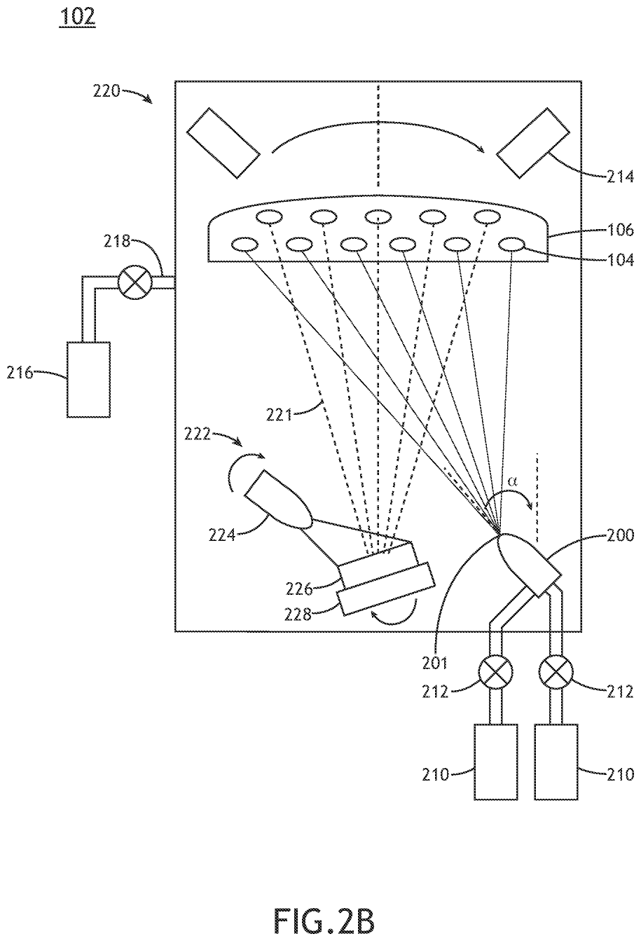

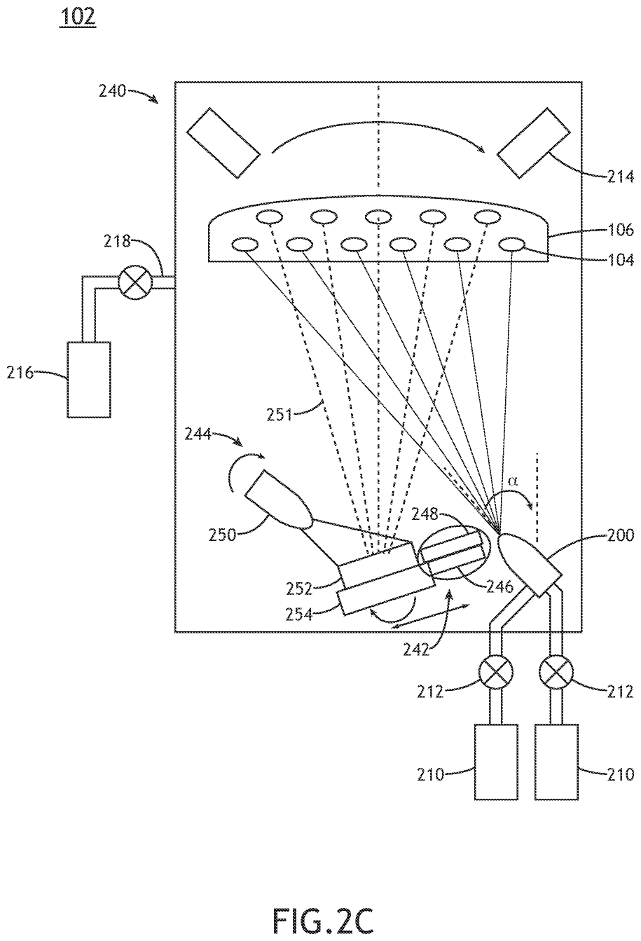

The system 100 may include a controller 110 communicatively coupled to the deposition sub-system 102. The controller 110 may include one or more processors configured to execute program instructions maintained on a memory medium. In this regard, the one or more processors of controller may execute any of the various process steps described throughout the present disclosure. For example, the controller 110 may be configured to control a sample stage, such as the sample stage 106 shown in FIG. 1. By way of another example, the controller 110 may be configured to control a sputtering target holder, such as the sputtering target holder 228 shown in FIG. 2B. By way of another example, the controller 110 may be configured to control a target holder, such as the target holder 254 shown in FIG. 2C.

FIGS. 2A-2C illustrate simplified schematic diagrams of the deposition sub-system 102, in accordance with one or more embodiments of the present disclosure. In particular, FIG. 2A depicts an ion-assisted evaporation deposition sub-system 200, in accordance with one or more embodiments of the present disclosure. In particular, FIG. 2B depicts an ion-assisted sputtering deposition sub-system 220, in accordance with one or more embodiments of the present disclosure. In particular, FIG. 2C depicts an ion-assisted sputtering and evaporation combination deposition sub-system 240, in accordance with one or more embodiments of the present disclosure.

Referring generally to FIGS. 2A-2C, in embodiments, the sub-system 102 (e.g., sub-systems 200, 220, 240) may include a low energy (<1 keV) ion source 202 configured to generate one or more low energy ion beams 201 and direct the one or more low energy ion beams 201 to the one or more samples 104 mounted on the sample stage 106. For example, the ion source 202 may be arranged at a select angle with respect to the one or more samples 104. In this regard, an ion beam impingement angle α may be adjusted by varying the ion source angle with respect to the one or more samples 104. The ion source 202 may be configured to generate any type of ions including, but not limited to, He, Ne, Ar, Xe, Kr, N, or the like.

The ion source 202 may include any type of ion source 202. For example, the sub-system 102 may include a filament-less ion source 202 configured to generate the one or more low energy ion beams 201. For instance, the sub-system 102 may include a filament-less ion gun 200 configured to eliminate heavy metal contamination as impurities to the deposited film. In this regard, the metal impurity in the optical coating (e.g., metal fluoride coating) may introduce additional absorption in the VUV spectral region to provide defect stabilization.

The low energy ion source 202 may be configured to generate one or more low energy ion beams 201 and direct the one or more low energy ion beams 201 simultaneously during evaporation and/or sputtering. For example, as shown in FIG. 2A, the sub-system 102 may include an ion-assisted evaporation deposition sub-system 200 configured to use the one or more low energy beams 201 from the ion source 202 during evaporation for generation of one or more optical coatings 108 with high EUV/VUV optical performance. By way of another example, as shown in FIG. 2B, the sub-system 102 may include an ion-assisted sputtering deposition sub-system 220 configured to use the one or more low energy beams 201 from the ion source 202 during sputtering for generation of one or more optical coatings 108 with high EUV/VUV optical performance. By way of another example, as shown in FIG. 2C, the sub-system 102 may include an ion-assisted sputtering and evaporation combination deposition sub-system 240 configured to use the one or more low energy beams 201 from the ion source 202 during evaporation and/or sputtering for generation of one or more optical coatings 108 with high EUV/VUV optical performance.

Referring to FIG. 2A, in embodiments, the ion-assisted evaporation deposition sub-system 200 may include an evaporation assembly 204 including an evaporator 206 and an evaporating target 208. For instance, the evaporator 206 may be configured to directly evaporate target material 205 from the evaporating target 208 to a surface of the one or more samples 104. The evaporation assembly 204 may include any type of evaporator 206. For example, the evaporation assembly 204 may include a thermal evaporator 206. By way of another example, the evaporation assembly 204 may include an electron beam evaporator 206.

It is noted that simultaneous evaporation (e.g., thermal evaporation, electron beam evaporation, and the like) with low energy ion beam bombardment from the low energy ion beam source may enhance surface diffusion of adatoms, while minimizing interstitial atoms and vacancies.

Referring to FIG. 2B, in embodiments, the ion-assisted sputtering deposition sub-system 220 may include a sputtering assembly 222 including a sputtering ion source 224 and one or more sputtering targets 226. For instance, the sputtering ion source 224 may be configured to sputter target material 221 from the sputtering target 226 to a surface of the one or more samples 104. The sputtering ion source 224 may include a high energy filament-less ion gun 222 configured to sputter target material 221 from the sputtering target 226 onto a surface of the one or more samples 104 to deposit the target material 221 onto the one or more samples 104.

The one or more sputtering targets 226 may include a plurality of sputtering targets 226 mounted on a sputtering target holder 228. For example, the plurality of sputtering targets 226 may be mounted on a rotatable sputtering target holder 228 configured to rotate the plurality of sputtering targets 226 to adjust an orientation of the targets 226, such that a high energy ion beam sputtering angle may be adjusted with respect to the one or more samples 104 and the low energy ion source angle relative to the one or more samples 104 may be adjusted independently during ion-assisted deposition. In this regard, the sub-system 220 may be configured to perform multilayer deposition.

Referring to FIG. 2C, in embodiments, the ion-assisted sputtering and evaporation combination deposition sub-system 240 may include an evaporation assembly 242 and a sputtering assembly 244. The evaporation assembly 242 may include an evaporator 246 and an evaporating target 248. The sputtering assembly 244 may include a sputtering ion source 250 and a sputtering target 252. For example, the evaporating target 248 may be used for evaporation and the sputtering target 252 may be used for ion sputtering.

The evaporating target 248 and/or the sputtering target 252 may be disposed on a target holder 254. For example, the target holder 254 may be a rotatable target holder 254 configured to rotate the evaporating target 248 and/or the sputtering target 252. By way of another example, the target holder 254 may be a translatable target holder 254 configured to translate the evaporating target 248 and/or the sputtering target 252. By way of another example, the target holder 254 may be a rotatable and translatable target holder 254 configured to rotate and translate the evaporating target 248 and/or the sputtering target 252. In this regard, the target holder 254 may be configured to accommodate multiple sputtering and evaporation targets and adjust a position of the targets to allow target switching during coating deposition.

It is noted that the sub-system 240 may be configured to deposit metal films by ion-assisted sputtering using high energy sputtering ion source 250 of the sputtering assembly 244 and the low energy ion source 202, followed by metal fluoride coating deposition using ion-assisted evaporation using the evaporating assembly 242. In this regard, the sub-system 240 may streamline the VUV mirror deposition process of direct depositing metal fluoride on metal coating (e.g., Al) to prevent metal film oxidation upon environment to ambient environment.

The low energy ion source 202 may be coupled to one or more working gas supplies 210 via one or more gas inlets 212. The one or more working gas supplies 210 may be configured to direct the one or more low energy ion beams 201 to one or more surfaces of the one or more samples 104. Referring to FIGS. 2A and 2C, the one or more working gas supplies 210 may be configured to direct the one or more ion beams 201 to the one or more samples 104 during evaporation.

The one or more working gas supplies 210 may supply any type of gas. For example, the one or more working gas supplies 210 may supply one or more noble gases. By way of another example, the one or more f gas supplies 210 may supply one or more fluorine-containing gases.

The sub-system 102 (e.g., sub-systems 200, 220, 240) may include a radiative heater 214 positioned proximate to the one or more samples 104 mounted on the sample stage 106. For example, the radiative heater 214 may be configured to heat the one or more samples 104.

The sub-system 102 (e.g., sub-systems 200, 220, 240) may be coupled to a fluorine gas supply source 216 via an inlet 218. The fluorine gas supply source 216 may be configured to provide the sub-system 102 with one or more fluorine ions. For example, the gas inlet 218 may be configured to couple the fluorine gas source 216 to the sub-system 102, such that the fluorine gas source 216 may be configured to provide the sub-system 102 with one or more fluorine ions. In one instance, the gas source 216 may be configured to provide fluorine rich gas during the coating production process. In another instance, the gas source 216 may be configured to provide fluorine rich gas during the fabrication process. In another instance, the gas source 216 may be configured to provide fluorine rich gas during post-deposition treatment (e.g., sample annealing by radiative heater 214). The gas inlet may include any source of fluorine ions including, but not limited to, XeF₂, NF₃, HF, F₂, CF₄, SF₆, NF₃, C₂F₆, or the like.

It is noted that post treatment annealing in high vacuum and F-containing environment may be implemented with the metal fluoride deposition of the system 100 to remove color centers, such as F-centers and M-centers, to improve optical performance and increase metal:fluorine stoichiometry to their respective nominal values.

Generation of a rich fluorine environment is generally discussed in U.S. patent application Ser. No. 17/393,932 entitled Fluorine Doped Optics for UV and VUV Applications, filed on Aug. 4, 2021 and U.S. patent application Ser. No. 17/393,953 entitled In-situ ion beam method for VUV optical component recovery, filed on Aug. 4, 2021, both of which are incorporated by reference herein in the entirety.

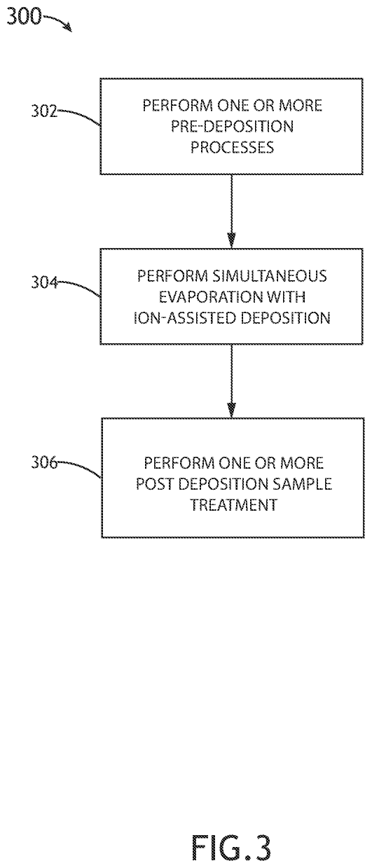

FIG. 3 illustrates a flow diagram 300 depicting a method or process of depositing one or more layers of one or more optical coatings onto a surface of a sample using the ion-assisted evaporation deposition sub-system 200, in accordance with one or more embodiments of the present disclosure. Applicant notes that the embodiments and enabling technologies described previously herein in the context of the fabrication system 100 and/or the deposition sub-system 102, 200 should be interpreted to extend to the method 300. It is further noted, however, that the method 300 is not limited to the architecture of the fabrication system 100 and/or the deposition sub-system 102, 200.

In an optional step 302, one or more pre-deposition processes may be performed. For example, in-situ sample cleaning may be performed. For instance, the sub-system 102 may be configured to perform in-situ sample cleaning on the one or more samples 104 disposed on the sample stage 106. By way of another example, noble gas ion sputtering may be performed. For instance, the sub-system 102 may be configured to perform noble gas ion sputtering using the low energy ion source 200.

In step 304, simultaneous evaporation and ion-assisted deposition. For example, the sub-system 200 may be configured to perform simultaneous evaporation using the evaporation assembly 204 and ion-assisted deposition using the low energy ion beam source 202. For instance, the sub-system 200 may be configured to use the low energy ion beam 201 from the low energy ion bean source 200 during evaporation for generation of the one or more optical coatings with high EUV/VUV optical perform. In this regard, during evaporation, the evaporator 206 may be configured to directly evaporate target material from the evaporating target 208 onto a surface of the one or more samples 104.

In an optional step 306, one or more post deposition sample treatments may be performed. For example, the sub-system 200 may be configured to perform post-deposition treatment annealing using the radiative heater 214 in the fluorine rich environment. In one instance, the low energy ion beam source 202 may be configured to provide fluorine ions via the one or more working gas supplies supplying fluorine gas. In another instance, the fluorine gas supply source 216 may be configured to provide fluorine ions via the gas inlet 218.

It is noted that post treatment annealing in high vacuum and F-containing environment may be implemented in metal fluoride deposition process to remove color center, such as F-centers and M-centers, to improve optical performance and to increase metal:fluorine ion stochiometry to their respective nominal values.

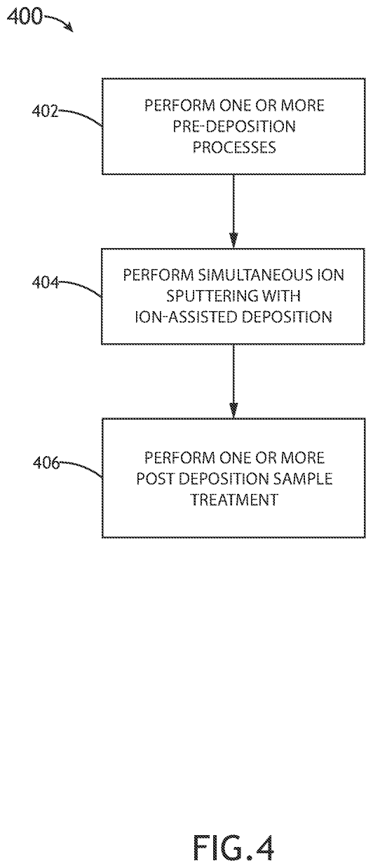

FIG. 4 illustrates a flow diagram 400 depicting a method or process of depositing one or more layers of one or more optical coatings onto a surface of a sample using the ion-assisted sputtering deposition sub-system 220, in accordance with one or more embodiments of the present disclosure. Applicant notes that the embodiments and enabling technologies described previously herein in the context of the fabrication system 100 and/or the deposition sub-system 102, 220 should be interpreted to extend to the method 400. It is further noted, however, that the method 400 is not limited to the architecture of the fabrication system 100 and/or the deposition sub-system 102, 220.

In an optional step 402, one or more pre-deposition processes may be performed. For example, in-situ sample cleaning may be performed. For instance, the sub-system 102 may be configured to perform in-situ sample cleaning on the one or more samples 104 disposed on the sample stage 106. By way of another example, noble gas ion sputtering may be performed. For instance, the sub-system 102 may be configured to perform noble gas ion sputtering using the ion beam source 200.

In step 404, ion sputtering may be simultaneously performed with ion-assisted deposition. For example, the sub-system 220 may be configured to perform simultaneous sputtering using the sputtering assembly 222 and ion-assisted deposition using the low energy ion beam source 202. For instance, the sub-system 220 may be configured to use the low energy ion beam 201 from the low energy ion bean source 200 during sputtering for generation of the one or more optical coatings with high EUV/VUV optical performance. In this regard, during sputtering, the sputtering ion source 224 may be configured to directly sputter target material from the sputtering target 226 onto a surface of the one or more samples 104.

In an optional step 406, one or more post deposition sample treatments may be performed. For example, the sub-system 220 may be configured to perform post-deposition treatment annealing using the radiative heater 214 in the fluorine rich environment. In one instance, the low energy ion beam source 202 may be configured to provide fluorine ions via the one or more working gas supplies supplying fluorine gas. In another instance, the fluorine gas supply source 216 may be configured to provide fluorine ions via the gas inlet 218.

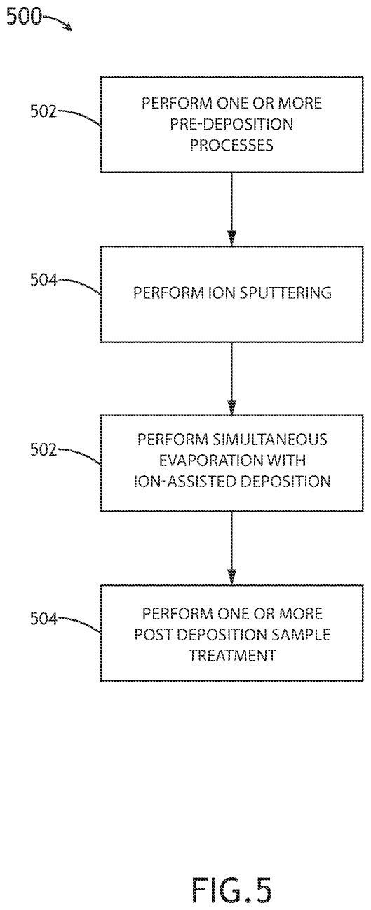

FIG. 5 illustrates a flow diagram 500 depicting a method or process of depositing one or more layers of one or more optical coatings onto a surface of a sample, in accordance with one or more embodiments of the present disclosure. Applicant notes that the embodiments and enabling technologies described previously herein in the context of the fabrication system 100 and/or the deposition sub-system 102 should be interpreted to extend to the method 500. It is further noted, however, that the method 500 is not limited to the architecture of the fabrication system 100 and/or the deposition sub-system 102.

In an optional step 502, one or more pre-deposition processes may be performed. For example, in-situ sample cleaning may be performed. For instance, the sub-system 102 may be configured to perform in-situ sample cleaning on the one or more samples 104 disposed on the sample stage 106. By way of another example, noble gas ion sputtering may be performed. For instance, the sub-system 102 may be configured to perform noble gas ion sputtering using the low energy ion beam source 200.

In step 504, ion sputtering may be performed. For example, the sub-system 240 may be configured to perform ion sputtering using the sputtering assembly 244. For example, the sputtering ion source 250 may be configured to sputter target material from the sputtering target 252 onto a surface of the one or more samples 104. For instance, the sputtering ion source 250 may be configured to sputter a first layer of target material from the sputtering target 252 onto a surface of the one or more samples 104.

In step 506, evaporation may be performed. For example, the sub-system 240 may be configured to perform evaporation using the evaporation assembly 242. For example, the evaporator 246 may be configured to directly evaporate target material from the evaporating target 248 onto a surface of the one or more samples 104. For instance, the evaporator 246 may be configured to evaporate a second layer of target material from the evaporating target 248 onto a surface of the one or more samples 104.

In an optional step 508, one or more post deposition sample treatments may be performed. For example, the sub-system 240 may be configured to perform post-deposition treatment annealing using the radiative heater 214 in the fluorine rich environment. In one instance, the low energy ion beam source 202 may be configured to provide fluorine ions via the one or more working gas supplies supplying fluorine gas. In another instance, the fluorine gas supply source 216 may be configured to provide fluorine ions via the gas inlet 218.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. An apparatus comprising:
a low energy ion beam source configured to generate one or more low energy ion beams and direct the one or more low energy beams to a surface of one or more samples mounted on a sample stage, the low energy ion beam source configured to couple to one or more working gas supplies;
a radiative heater positioned proximate to the one or more samples disposed on the sample stage, the radiative heater configured to heat the one or more samples;
a gas inlet coupled to a fluorine gas supply source;
an evaporator assembly, the evaporator assembly comprising:
an evaporator; and
an evaporating target, the evaporator configured to directly evaporate target material from the evaporating target to a surface of the one or more samples, the apparatus configured to use the one or more low energy ion beams from the low energy ion beam source during evaporation from the evaporator assembly for generation of one or more optical coatings on a surface of the one or more samples.

2. The apparatus of claim 1, further comprising:
a sputtering assembly, the sputtering assembly comprising:
a sputtering ion source; and
a sputtering target, the sputtering ion source configured to sputter target material from the sputtering target onto a surface of the one or more samples.

3. The apparatus of claim 2, further comprising:
one or more target holders, at least of the evaporating target or the sputtering target mountable on the one or more target holders, the one or more target stages configured to adjust a position of the at least evaporating target or the sputtering target.

4. The apparatus of claim 1, wherein the one or more optical coatings comprise one or more metal fluoride coatings.

5. The apparatus of claim 1, wherein the low energy ion beam source comprises a filament-less ion gun.

6. The apparatus of claim 1, wherein the low energy ion beam source is arranged at a select angle with respect to the one or more samples.

7. The apparatus of claim 6, wherein a low energy ion beam impingement angle may be adjusted by varying the select angle of the low energy ion beam source with respect to the one or more samples.

8. The apparatus of claim 1, wherein the one or more low energy ion beam sources include at least one of a:
helium ion source, neon ion source, argon ion source, xenon ion source, krypton ion beam source, or nitrogen ion source.

9. The apparatus of claim 1, wherein the evaporator includes at least one of:
a thermal evaporator or an electron beam evaporator.

10. An apparatus comprising:
a low energy ion beam source configured to generate one or more low energy ion beams and direct the one or more low energy beams to a surface of one or more samples mounted on a sample stage, the low energy ion beam source configured to couple to one or more working gas supplies;
a radiative heater positioned proximate to the one or more samples disposed on the sample stage, the radiative heater configured to heat the one or more samples;
a gas inlet coupled to a fluorine gas supply source;
a sputtering assembly, the sputtering assembly comprising:
a sputtering ion source; and
a sputtering target, the sputtering ion source configured to sputter target material from the sputtering target onto a surface of the one or more samples,
the apparatus configured to use the one or more low energy ion beams from the low energy ion beam source during sputtering from the sputtering assembly for generation of one or more optical coatings on a surface of the one or more samples.

11. The apparatus of claim 10, further comprising:
an evaporator assembly, the evaporator assembly comprising:
an evaporator; and
an evaporating target, the evaporator configured to directly evaporate target material from the evaporating target to a surface of the one or more samples.

12. The apparatus of claim 11, further comprising:
one or more target holders, at least of the evaporating target or the sputtering target mountable on the one or more target holders, the one or more target stages configured to adjust a position of the at least evaporating target or the sputtering target.

13. The apparatus of claim 11, wherein the evaporator includes at least one of:
a thermal evaporator or an electron beam evaporator.

14. The apparatus of claim 10, wherein the one or more optical coatings include one or more metal fluoride coatings.

15. The apparatus of claim 10, wherein the low energy ion beam source includes a filament-less ion gun.

16. The apparatus of claim 10, wherein the low energy ion beam source is arranged at a select angle with respect to the one or more samples.

17. The apparatus of claim 16, wherein a low energy ion beam impingement angle may be adjusted by varying the select angle of the low energy ion beam source with respect to the one or more samples.

18. The apparatus of claim 10, wherein the one or more low energy ion beam sources include at least one of a:
helium ion source, neon ion source, argon ion source, xenon ion source, krypton ion beam source, or nitrogen ion source.

19. An apparatus comprising:
a low energy ion beam source configured to generate one or more low energy ion beams and direct the one or more low energy beams to a surface of one or more samples mounted on a sample stage, the low energy ion beam source configured to couple to one or more working gas supplies;
a radiative heater positioned proximate to the one or more samples disposed on the sample stage, the radiative heater configured to heat the one or more samples; and
a gas inlet coupled to a fluorine gas supply source,
the apparatus configured to use the one or more low energy ion beams from the low energy ion beam source during at least one of evaporation or sputtering for generation of one or more optical coatings on a surface of the one or more samples.

20. The apparatus of claim 19, further comprising:
an evaporator assembly, the evaporator assembly comprising:
an evaporator; and
an evaporating target, the evaporator configured to directly evaporate target material from the evaporating target to a surface of the one or more samples,

21. The apparatus of claim 19, further comprising:
a sputtering assembly, the sputtering assembly comprising:
a sputtering ion source; and
a sputtering target, the sputtering ion source configured to sputter target material from the sputtering target onto a surface of the one or more samples.

22. The apparatus of claim 19, further comprising:
an evaporator assembly, the evaporator assembly comprising:
an evaporator; and
an evaporating target, the evaporator configured to directly evaporate target material from the evaporating target to a surface of the one or more samples; and
a sputtering assembly, the sputtering assembly comprising:
a sputtering ion source; and
a sputtering target, the sputtering ion source configured to sputter target material from the sputtering target onto a surface of the one or more samples.

23. The apparatus of claim 22, further comprising:
one or more target holders, at least of the evaporating target or the sputtering target mountable on the one or more target holders, the one or more target stages configured to adjust a position of the at least evaporating target or the sputtering target.

24. The apparatus of claim 22, wherein the evaporator includes at least one of:
a thermal evaporator or an electron beam evaporator.

25. The apparatus of claim 19, wherein the one or more optical coatings include one or more metal fluoride coatings.

26. The apparatus of claim 19, wherein the low energy ion beam source includes a filament-less ion gun.

27. The apparatus of claim 19, wherein the low energy ion beam source is arranged at a select angle with respect to the one or more samples.

28. The apparatus of claim 27, wherein a low energy ion beam impingement angle may be adjusted by varying the select angle of the low energy ion beam source with respect to the one or more samples.

29. The apparatus of claim 19, wherein the one or more low energy ion beam sources include at least one of a:
helium ion source, neon ion source, argon ion source, xenon ion source, krypton ion beam source, or nitrogen ion source.

30. A method comprising:
performing one or more pre-deposition processes;
performing evaporation using an evaporation assembly of an ion-assisted deposition system during ion-assisted deposition using a low energy ion beam source of the ion-assisted deposition system, the evaporation assembly including an evaporating target and an evaporator configured to directly evaporate target material from the evaporating target onto a surface of the one or more samples, the low energy ion beam source configured to generate one or more low energy ion beams during evaporation to generate one or more optical coatings on a surface of the one or more samples; and
performing one or more post-deposition treatment processes.

31. The method of claim 30, wherein the performing one or more pre-deposition processes further comprises:
performing in-situ sample cleaning using the low energy ion beam source.

32. The method of claim 30, wherein the performing one or more pre-deposition processes further comprises:
performing noble gas ion sputtering using the low energy ion beam source.

33. The method of claim 30, wherein the performing one or more post-deposition treatment processes further comprises:
performing post-deposition treatment annealing using a radiative heater of the ion-assisted deposition system in a fluorine rich environment.

34. A method comprising:
performing one or more pre-deposition processes;
performing sputtering using a sputtering assembly of an ion-assisted deposition system during ion-assisted deposition using a low energy ion beam source of the ion-assisted deposition system, the sputtering assembly including a sputtering target and a sputtering high energy ion source configured to sputter target material from the sputtering target onto a surface of the one or more samples, the low energy ion beam source configured to generate one or more low energy ion beams during sputtering to generate one or more optical coatings on a surface of the one or more samples; and
performing one or more post-deposition treatment processes.

35. The method of claim 34, wherein the performing one or more pre-deposition processes further comprises:
performing in-situ sample cleaning using the low energy ion beam source.

36. The method of claim 34, wherein the performing one or more pre-deposition processes further comprises:
performing noble gas ion sputtering using the low energy ion beam source.

37. The method of claim 34, wherein the performing one or more post-deposition treatment processes further comprises:
performing post-deposition treatment annealing using a radiative heater of the ion-assisted deposition system in a fluorine rich environment.

38. A method comprising:
performing one or more pre-deposition processes;
performing sputtering using a sputtering assembly of an ion-assisted deposition system, the sputtering assembly including a sputtering target and a sputtering high energy ion source configured to sputter a first layer of target material from the sputtering target onto a surface of the one or more samples;
performing evaporation using an evaporation assembly of the ion-assisted deposition system, the evaporation assembly including an evaporating target and an evaporator configured to directly evaporate a second layer of target material from the evaporating target onto a surface of the one or more samples; and
performing one or more post-deposition treatment processes.

39. The method of claim 38, wherein the performing one or more pre-deposition processes further comprises:
performing in-situ sample cleaning using the low energy ion beam source.

40. The method of claim 38, wherein the performing one or more pre-deposition processes further comprises:
performing noble gas ion sputtering using the low energy ion beam source.

41. The method of claim 38, wherein the performing one or more post-deposition treatment processes further comprises:
performing post-deposition treatment annealing using a radiative heater of the ion-assisted deposition system in a fluorine rich environment.
